(19) United States
(12) Patent Application Publication
(10) Pub. No.: US 2014/0009184 A1
(43) Pub. Date: Jan. 9, 2014

(54) SEMICONDUCTOR CHIP TEST APPARATUS AND METHOD

(71) Applicant: Chen-Chung CHANG, New Taipei City (TW)

(72) Inventor: Chen-Chung CHANG, New Taipei City (TW)

(21) Appl. No.: 13/542,979

(22) Filed: Jul. 6, 2012

(51) Int. Cl. G01R 31/26

(52) U.S. Cl. 324/757.04

(57) ABSTRACT

A semiconductor chip test method used in a semiconductor chip test apparatus including an electric energy measurement unit defining multiple conducting pin holes in a recess of an electric energy test table for holding contact pins of a semiconductor chip for testing electric properties, a functional tester disposed adjacent to the electric energy measurement unit for testing predetermined functions of the semiconductor chip in a functional test table thereof and transmitting tested data to an external display screen through a display card, and a conveyer unit controllable to deliver the test semiconductor chip to the electric energy test table for electric energy measurement and to the functional test table of the functional tester for functional test.

### BACKGROUND OF THE INVENTION

1. Field of the Invention

The present invention relates to semiconductor chip test technology and more particularly, to a semiconductor chip test apparatus and method, which facilitates quick examination of electric properties and functions of semiconductor chips, shortening the test sample delivery path, saving much test sample delivery time, and greatly improving test sample testing efficiency.

2. Description of the Related Art

Following fast development of high technology, advanced electric and electronic products with expanded functions are continuously created for a wide range of applications to fit different requirements. In an electric or electronic product, one or a number of IC chips (MCU, monolithic chip, microprocessor, etc.) may be used to execute programs, to compute data and/or to control different operations. A semiconductor chip generally provides multiple contact pins for transmitting power and data signal. However, during the fabrication of a semiconductor chip, the bonding wire between the pad and the core may be displaced or broken, causing the respective contact pin unable to transmit power or data signal. Therefore, the electric properties of the contact pins of a semiconductor chip and its functioning must be examined carefully before application. An electric or electronic product using a defective semiconductor chip will be unable to function well.

Generally, a primary semiconductor chip testing procedure is performed on wafer or dies before individual chip packaging. After package, each individual semiconductor chip must be examined again. This semiconductor chip testing method is complicated. Further, because a finished semiconductor chip has a large number of contact pins, it is complicated to finish the test. In actual practice, conventional semiconductor chip test methods have drawbacks as follows:
(1) Any short circuit problem of the contact pins of a semiconductor chip may be not discovered prior to installation of the semiconductor chip in a circuit board. If a short circuit problem occurs after installation of a semiconductor chip in a circuit board, the semiconductor chip must be removed from the circuit board, wasting must time and labor.
(2) A mechanical arm is generally used to deliver a semiconductor chip during testing or installation. However, the contact pins of the semiconductor chip may be curved, damaged or broken accidentally due to inaccurate positioning or an impact against an external object during delivery, causing the semiconductor chip unable to transmit power or data signal normally.

Therefore, it is desirable to provide an apparatus for testing semiconductor chips that eliminates the aforesaid problems.

### SUMMARY OF THE INVENTION

The present invention has been accomplished under the circumstances in view. It is therefore the main object of the present invention to provide a semiconductor chip test apparatus and method, which is practical for testing electric properties and functions of semiconductor chips conveniently and rapidly, shortening the test sample delivery path, saving much test sample delivery time, and greatly improving test sample testing efficiency.

To achieve this and other object of the present invention, a semiconductor chip test apparatus comprises an electric energy measurement unit for measuring the electric properties of the semiconductor chip to be tested, a functional tester for testing predetermined functions of the test semiconductor chip, and a conveyer unit for delivering the test semiconductor chip to the electric energy measurement unit and the functional tester for testing. The electric energy measurement unit comprises an electric energy test table, a recess defined in the electric energy test table for holding the test semiconductor chip, a plurality of conducting pin holes formed in the recess of the electric energy test table for electrically receiving contact pins of the test semiconductor chip, and a console electrically connected with the conducting pin holes for controlling the electric energy measurement unit to measure the electric properties of the test semiconductor chip. The functional tester is disposed adjacent to the electric energy measurement unit, comprising a circuit board, a functional test table disposed at the top side of the circuit board for holding the test semiconductor chip for test, and a display card arranged on the circuit board and providing at least one electrical connector for data output to an external display screen for displaying test results. The conveyer unit is disposed at one side relative to the electric energy measurement unit and the functional tester, and controllable to deliver the test semiconductor chip to the electric energy test table for electric energy measurement and to the functional test table for functional test.

Further, the electric energy measurement unit, the conveyer unit and the functional tester are arranged on a platform, facilitating quick examination of electric properties and functions of each semiconductor chip.

### BRIEF DESCRIPTION OF THE DRAWINGS

FIG. 1 is an elevational view of a semiconductor chip test apparatus in accordance with the present invention.

FIG. 2 is an enlarged view of Part A of FIG. 1.

FIG. 3 is a schematic drawing of the present invention, illustrating the vacuum suction head of the conveyer unit lowered and a test semiconductor chip delivered to the electric energy test table of the electric energy measurement unit.

FIG. 4 corresponds to FIG. 3, illustrating the slide holder of the conveyer unit moved along the sliding track from a position adjacent to the electric energy test table of the electric energy measurement unit to a position adjacent to the functional test table of the functional tester.

FIG. 5 is a side view of the present invention, illustrating movement of the slide holder of the conveyer unit moved along the sliding track between the electric energy measurement unit and the functional tester.

FIG. 6 is a flow chart of a semiconductor chip test method in accordance with the present invention (I).

FIG. 7 is a flow chart of a semiconductor chip test method in accordance with the present invention (II).

### DETAILED DESCRIPTION OF THE PREFERRED EMBODIMENT

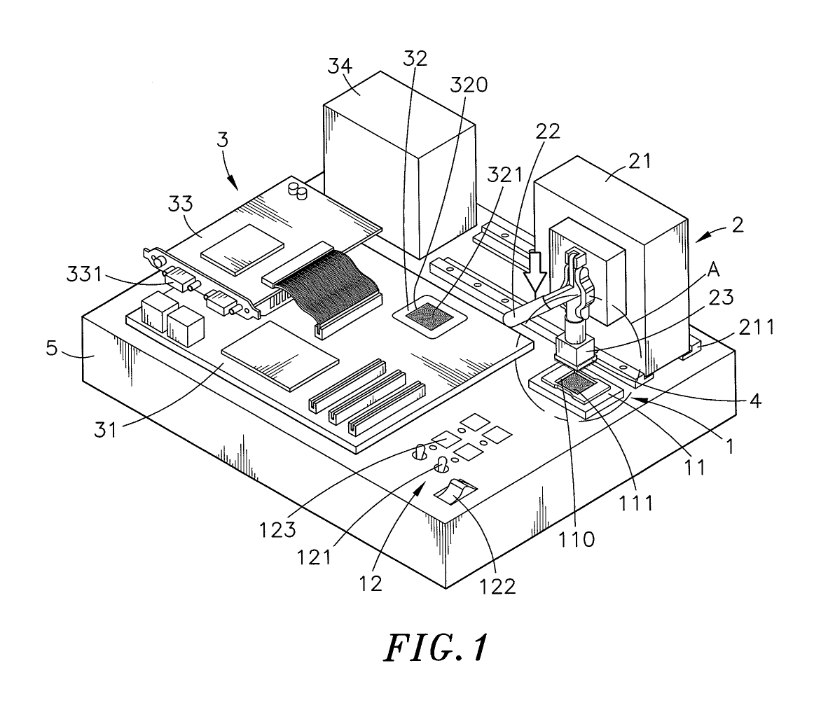

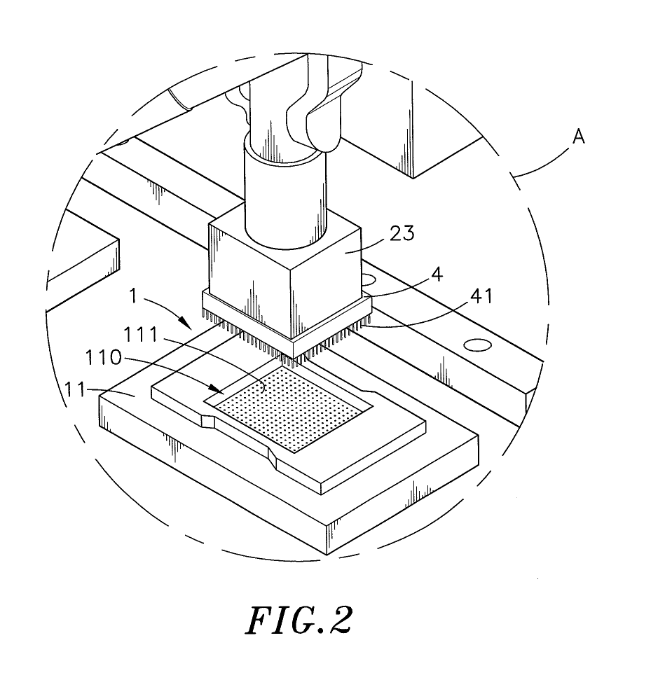

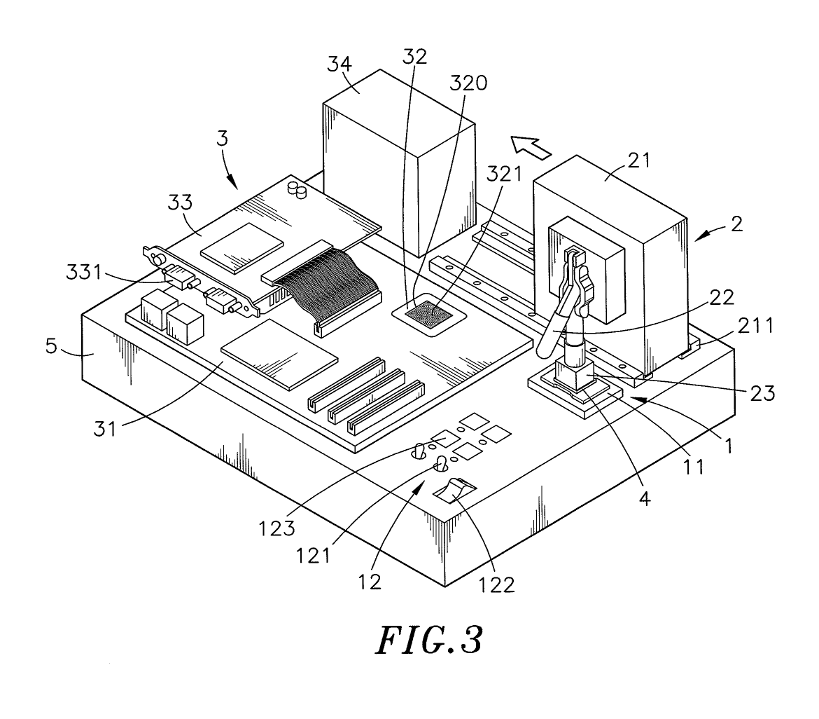

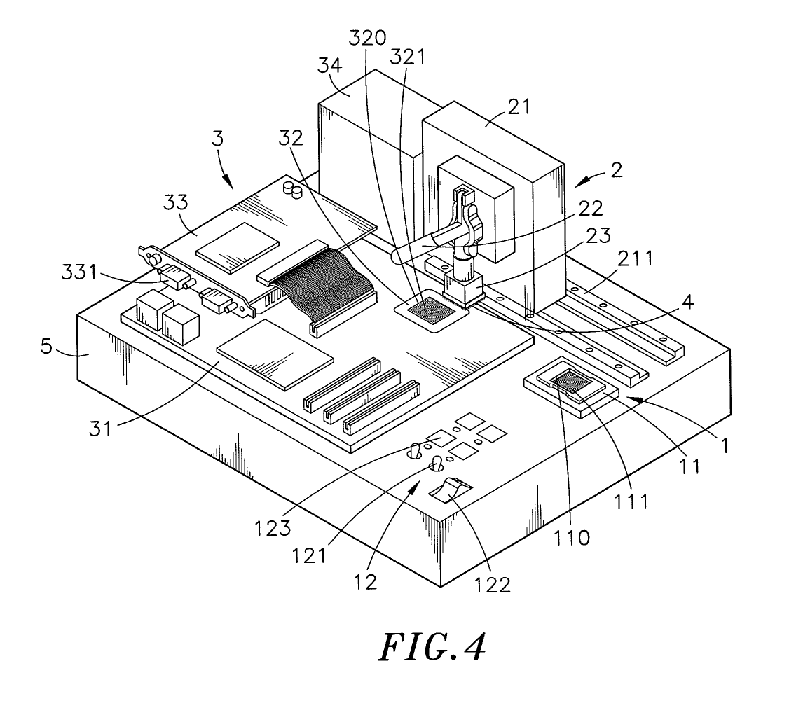

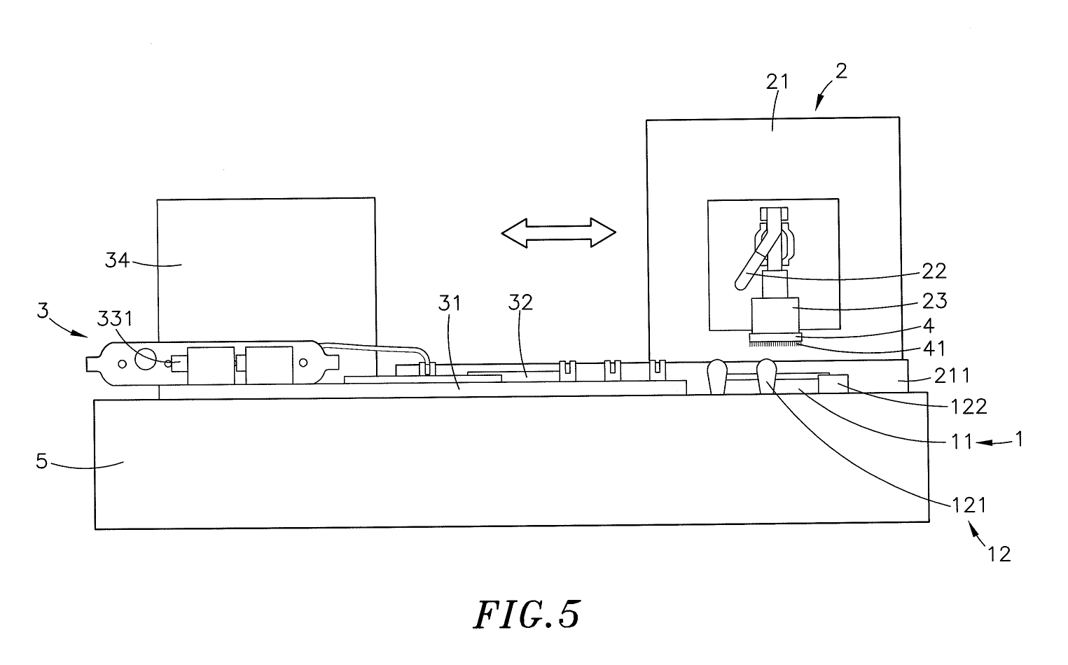

Referring to FIGS. 1-5, a semiconductor chip test apparatus in accordance with the present invention is shown comprising an electric energy measurement unit 1, a conveyer unit 2, and a functional tester 3.

The electric energy measurement unit 1 comprises an electric energy test table 11, a recess 110 defined in the electric energy test table 11, a plurality of conducting pin holes 111 formed in the recess 110, and a console 12 electrically connected with the conducting pin holes 111. The console 12 comprises a plurality of switches 121 and a button 122 for electric energy measurement control, and a plurality of indicator lights 123 for the indication of measurement results.

The conveyer unit 2 comprises a slide holder 21 movable back and forth along a sliding track 211, an operating handle 22 provided at the front side of the slide holder 21, and a vacuum suction head 23 coupled to the sliding holder 21 and movable up and down relative to the slide holder 21 by the operating handle 22.

The functional tester 3 comprises a circuit board 31, a functional test table 32 disposed at the top side of the circuit board 31, a recess 320 defined in the functional test table 32, a plurality of conducting pin holes 321 formed in the recess 320 and electrically coupled to the circuit board 31, a display card 33 arranged on the circuit board 31 and providing at least one electrical connector 331 for data output, and a power supply unit 34 electrically connected to the circuit board 31 to provide the functional tester 3 with the necessary working voltage. Further, the electrical connector 331 can be a USB 2.0/3.0 connector, HDMI connector, or DVI connector.

During installation, affix the sliding track 211 at one lateral side relative to the electric energy test table 11 of the electric energy measurement unit 1, and then couple the slide holder 21 of the conveyer unit 2 to the sliding track 211 to suspend the operating handle 22 and the vacuum suction head 23 above the recess 110 of the electric energy test table 11 of the electric energy measurement unit 1, and then mount the circuit board 31 of the functional tester 3 at one lateral side relative to the electric energy measurement unit 1 and the conveyer unit 2 to hold the functional test table 32 in such a position that when the sliding track 21 is moved to one end of the sliding track 211 away from the electric energy test table 11 of the electric energy measurement unit 1, the operating handle 22 and the vacuum suction head 23 is suspending above the recess 320 of the functional test table 32, and electrically connect the electrical connector 331 of the display card 33 to an external display screen (computer monitor, LCD screen, LED screen, electronic picture frame, tablet PC or notebook computer) for display test data provided by the electric energy measurement unit 1 and the functional tester 3.

Further, the electric energy measurement unit 1, the conveyer unit 2 and the functional tester 3 can be mounted on a platform 5, keeping the electric energy test table 11 of the electric energy measurement unit 1 and the functional test table 32 of the functional tester 3 at one lateral side relative to the sliding track 211 and slide holder 21 of the conveyer unit 2. Thus, the slide holder 21 can be moved along the sliding track 211 to suspend the operating handle 22 and the vacuum suction head 23 above the recess 110 of the electric energy test table 11 of the electric energy measurement unit 1 or the recess 320 of the functional test table 32 of the functional tester 3, enabling the vacuum suction head 23 to carry a semiconductor chip 4 to the recess 110 of the electric energy test table 11 of the electric energy measurement unit 1 or the recess 320 of the functional test table 32 of the functional tester 3 for examination. Further, the power supply unit 34 of the functional tester 3 can be a storage battery, dry battery, rechargeable battery, AC adapter, or power generator. Further, the conveyer unit 2 and the functional tester 3 are respectively electrically connected to the console 12 of the electric energy measurement unit 1. Subject to the control of the console 12, semiconductor chips 4 are tested in the electric energy test table 11 of the electric energy measurement unit 1 and the functional test table 32 of the functional tester 3.

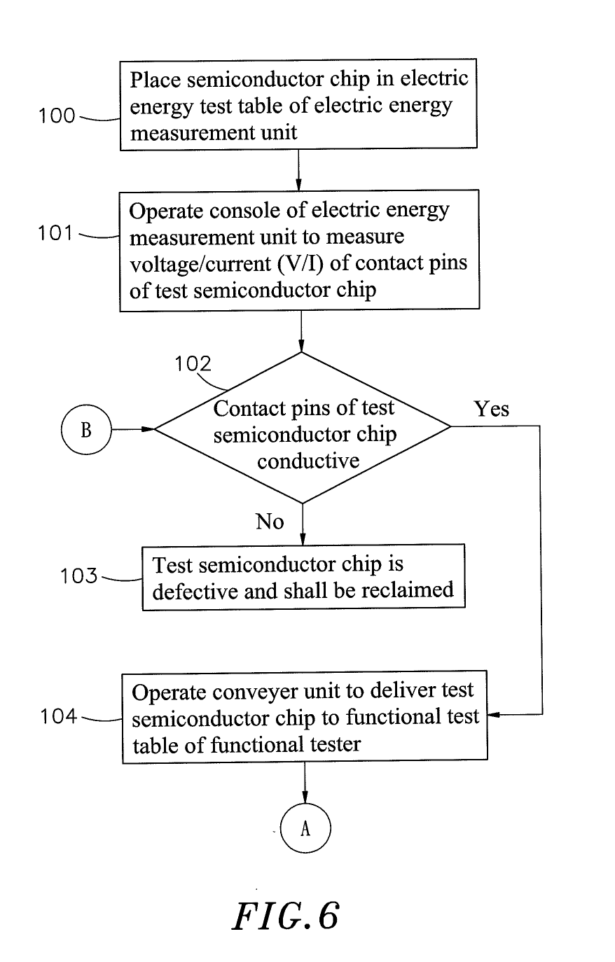

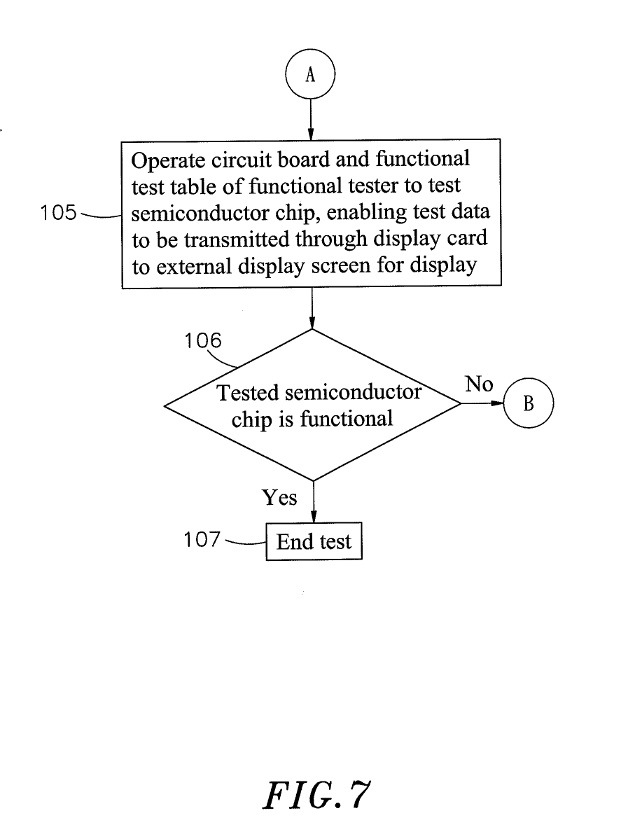

Referring to FIGS. 6 and 7 and FIGS. 1-5 again, the aforesaid semiconductor chip test apparatus is operated subject to the following steps:
(100) Operate the vacuum suction head 23 of the conveyer unit 2 to deliver the semiconductor chip 4 to be tested to the recess 110 of the electric energy test table 11 of the electric energy measurement unit 1.
(101) Operate the console 12 of the electric energy measurement unit 1 to measure the electric properties of voltage/current (V/I) of the test semiconductor chip 4 in the recess 110 of the electric energy test table 11 of the electric energy measurement unit 1.
(102) Determine whether or not the contact pins 41 of the test semiconductor chip 4 are electrically conductive? And then, proceed to step (103) if negative, or step (104) if positive.
(103) If the contact pins 41 are all or partially short-circuited, the test semiconductor chip 4 is determined to be defective and shall be reclaimed.
(104) Operate the vacuum suction head 23 of the conveyer unit 2 to deliver the test semiconductor chip 4 to the recess 320 of the functional test table 32 of the functional tester 3.
(105) Operate the circuit board 31 and functional test table 32 of the functional tester 3 to test the test semiconductor chip 4, enabling the test data to be transmitted through the display card 33 to the external display screen for display.
(106) Determine whether or not the tested semiconductor chip 4 is functional? And then return to step (103) if negative, or proceed to step (107) if positive.
(107) The tested semiconductor chip 4 is functional and can be installed in a circuit board or mainboard of a predetermined electronic or electric product, and then end the test procedure.

As stated above, the conducting pin holes 111 in the recess 110 of the electric energy test table 11 are respectively electrically connected to the console 12. When starting the test procedure, the vacuum suction head 23 at the front side of the slide holder 21 of the conveyer unit 2 is operated to pick up the semiconductor chip 4 to be tested and to place the test semiconductor chip 4 in the recess 110 of the electric energy test table 11 of the electric energy measurement unit 1, inserting the contact pins 41 of the test semiconductor chip 4 into the conducting pin holes 111 in the recess 110 of the electric energy test table 11 of the electric energy measurement unit 1. Thereafter, the console 12 is operated to measure the electric properties of voltage/current (V/I) of the test semiconductor chip 4 by a 4-wire measuring loop. At this time, two of the 4-wire measuring loop are for measuring an applied constant voltage, and the other two of the 4-wire loop are for measuring an applied constant current. The applied constant voltage can be within the range of 0.1V˜3.3V. The applied constant current can be within the range of 0.1 m˜2 mA. The testing time can be, for example, 30 seconds, 35 seconds, or 60 seconds, subject to the type of the semiconductor chip 4 to be tested. By means of measuring the impedance (symbol Z) of the bonding wire between the core and pad of the test semiconductor chip 4, “Open” or “Short” status of the respective bonding wire is determined, and therefore the conducted or disconducted status of the contact pins 41 of the test semiconductor chip 4 is determined. If the contact pins 41 of the test semiconductor chip 4 are conducted, the test semiconductor chip 4 is determined to be a good product, and a further test procedure can be continued. If the contact pins 41 of the test semiconductor chip 4 are disconducted, the test semiconductor chip 4 is determined to be a defective product and must be reclaimed.

When running a test procedure through the electric energy measurement unit 1, the switches 121 and button 122 of the console are operated to measure the electric energy of the test semiconductor chip, and the test result can be displayed by means of the indicator lights 123. The indicator lights 123 can give off red, yellow, blue, green and/or other colors of light for visual indication of the conditions of “Normal”, “Failure”, “Under Test”, “Open”, “Short”, and etc.

After tested through the electric energy measurement unit 1, the test semiconductor chip 4 is picked up from the recess 110 of the electric energy test table 11 of the electric energy measurement unit 1 and delivered to the recess 320 of the functional test table 32 of the functional tester 3 by the vacuum suction head 23, enabling the contact pins 41 of the test semiconductor chip 4 to be respectively inserted into the respective conducting pin holes 321 in the recess 320. Thereafter, the circuit board 31 is electrically conducted by the power supply unit 34 to run the test semiconductor chip 4 subject to predetermined operating, computing, signal processing, signal transmitting and/or signal storing programs. The test data is then transmitted through the electrical connector 331 of the display card 33 to the external display screen (computer monitor, LCD screen, LED screen, electronic picture frame, tablet PC or notebook computer) for display. At this time, the test semiconductor chip 4 can be determined to be a good product or defective product. If the test semiconductor chip 4 is examined to be normal, it is a good product and can be used for further installation application. If the test semiconductor chip 4 is examined to be abnormal, it is a defective product and should be reclaimed.

The conducting status of the contact pins 41 of each test semiconductor chip 4 is examined at first before functional test, avoiding wasting time and labor in examining a short-circuited defective semiconductor chip. Thus, only functional semiconductor chips can pass the test for further application, avoiding the use of defective semiconductor chips.

As stated, the invention provides a semiconductor chip test apparatus consisting of an electric energy measurement unit 1, a conveyer unit 2 and a functional tester 3, and a test method using this semiconductor chip test apparatus. By means of the vacuum suction head 23 of the conveyer unit 2, every test semiconductor chip 4 can be delivered to the electric energy test table 11 of the electric energy measurement unit 1 for electric energy measurement, and then delivered to the functional test table 32 of the functional tester 3 for functional test after passed the electric energy measurement. After test, each functional semiconductor chip can be collected for further application, and any defective semiconductor chip will be reclaimed.

In conclusion, the invention provides a semiconductor chip test apparatus and method, having advantages and features as follows:
(A) Before installation of a semiconductor chip 4 in a circuit board of an electronic or electric product, the electric properties of the contact pins 41 of the semiconductor chip 4 are measured by the electric energy measurement unit 1, and then, the semiconductor chip 4, after passed the electric energy measuring process, is functionally examined by the functional tester 3.
(B) The electric energy measurement unit 1 and the functional tester 3 are closely arranged at one side relative to the conveyer unit 2 so that the vacuum suction head 23 of the conveyer unit 2 can deliver every test semiconductor chip 4 to the electric energy measurement unit 1 and the functional tester 3 conveniently and rapidly for test, shortening the test sample delivery path and saving much test sample delivery time.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A semiconductor chip test apparatus, comprising:
an electric energy measurement unit for measuring the electric conducting status of a test semiconductor chip, said electric energy measurement unit comprising an electric energy test table, a recess defined in said electric energy test table for holding the test semiconductor chip, a plurality of conducting pin holes formed in the recess of said electric energy test table for electrically receiving contact pins of the test semiconductor chip, and a console electrically connected with said conducting pin holes for controlling said electric energy measurement unit to measure the electric properties of the test semiconductor chip;
a functional tester disposed adjacent to said electric energy measurement unit for testing predetermined functions of the test semiconductor chip, said functional tester comprising a circuit board, a functional test table disposed at a top side of said circuit board for holding the test semiconductor chip for test, and a display card arranged on said circuit board and providing at least one electrical connector for data output to an external display screen for displaying test results; and
a conveyer unit disposed at one side relative to said electric energy measurement unit and said functional tester and controllable to deliver the test semiconductor chip to said electric energy test table for electric energy measurement and to said functional test table for functional test.

2. The semiconductor chip test apparatus as claimed in claim 1, further comprising a platform supporting said electric energy measurement unit, said functional tester and said conveyer unit, and a sliding track arranged on said platform adjacent to said electric energy test table of said electric energy measurement unit and said functional test table of said functional tester, said conveyer unit being supported on said sliding track and movable along said sliding track between said electric energy test table of said electric energy measurement unit and said functional test table of said functional tester.

3. The semiconductor chip test apparatus as claimed in claim 1, wherein said electric energy measurement unit has built therein a 4-wire testing loop for measuring the electric properties of voltage/current (V/I) of the test semiconductor chip.

4. The semiconductor chip test apparatus as claimed in claim 1, wherein said conveyer unit comprises a slide holder supported on and movable along said sliding track, a vacuum suction head coupled to said slide holder and adapted for picking up the semiconductor chip to be tested.

5. The semiconductor chip test apparatus as claimed in claim 1, wherein said circuit board of said functional tester is a computer mainboard carrying a circuit layout and a plurality of electronic components.

6. The semiconductor chip test apparatus as claimed in claim 1, wherein said at least one electrical connector of said display card of said functional tester is selected from the group of USB connectors, HDMI connectors and DVI connectors.

7. A semiconductor chip test method used in the semiconductor chip test apparatus as claimed in claim 1, comprising the steps of:
(a) placing the semiconductor chip to be tested in the electric energy test table of the electric energy measurement unit;
(b) operating the console of the electric energy measurement unit to measure the electric properties of voltage/current (V/I) of contact pins of the test semiconductor chip in the electric energy test table of the electric energy measurement unit;
(c) determining the electric conductive status of the contact pins of the test semiconductor chip, and then proceeding to step (d) if the contact pins are not conductive, or step (e) if the contact pins are conductive;
(d) determining the test semiconductor chip to be a defective semiconductor chip;
(e) operating the conveyer unit to deliver the test semiconductor chip to the functional test table of the functional tester;
(f) operating the circuit board and functional test table of the functional tester to test the test semiconductor chip, enabling the test data to be transmitted through the display card to an external display screen for display;
(g) determining the tested semiconductor chip to be a functional semiconductor chip or defective semiconductor chip, and then returning to step (d) if the tested semiconductor chip is a defective semiconductor chip, or proceeding to step (h) if the tested semiconductor chip is a functional semiconductor chip; and
(h) ending the test.

8. The semiconductor chip test method as claimed in claim 7, wherein the electric energy measurement unit, functional tester and conveyer unit of the semiconductor chip test apparatus are supported on a platform, and the conveyer unit of the semiconductor chip test apparatus is supported on a sliding track at the platform and movable along the sliding track between the electric energy test table of the electric energy measurement unit and the functional test table of the functional tester.

9. The semiconductor chip test method as claimed in claim 7, wherein the electric energy measurement unit has built therein a 4-wire testing loop for measuring the electric properties of voltage/current (V/I) of the test semiconductor chip, two of the 4-wire measuring loop being adapted for measuring an applied constant voltage, and the other two of the 4-wire loop being adapted for measuring an applied constant current.

10. The semiconductor chip test method as claimed in claim 7, wherein the applied constant voltage is within the range of 0.1V˜3.3V, the applied constant current us within the range of 0.1 mA˜2 mA.
